(19) United States
(12) Patent Application Publication
(10) Pub. No.: US 2016/0247982 A1
(43) Pub. Date: Aug. 25, 2016

(54) LIGHT-EMITTING DEVICE

(71) Applicant: Genesis Photonics Inc., Tainan City (TW)

(72) Inventors: Shao-Ying Ting, Tainan City (TW); Sie-Jhan Wu, Tainan City (TW); Jing-En Huang, Tainan City (TW)

(21) Appl. No.: 15/045,454

(22) Filed: Feb. 17, 2016

Related U.S. Application Data
(60) Provisional application No. 62/116,923, filed on Feb. 17, 2015.

(51) Int. Cl. H01L 33/56; H01L 33/62

(52) U.S. Cl. CPC H01L 33/56; H01L 33/62

(57) ABSTRACT

A light-emitting device including a light-emitting unit, an electrode unit, and an insulating unit is provided. The light-emitting unit includes an illuminator and a packaging sealant. The illuminator generates an optical energy by way of electroluminescence, and the packaging sealant is formed on a part of a surface of the illuminator. The electrode unit includes a first electrode and a second electrode respectively formed on the surface of the illuminator on which no packaging sealant is formed. The insulating unit is formed on the surface of the light-emitting unit and includes a first insulating layer protruded between the first electrode and the second electrode. When the light-emitting device of the invention is electrically connected to an external circuit board using solder, the insulating unit effectively separates the elements to avoid the elements being short-circuited by the solder overflowing.

This application claims the benefit of U.S. provisional application Ser. No. 62/116,923, filed Feb. 17, 2015, the disclosure of which is incorporated by reference herein in its entirety.

### TECHNICAL FIELD

The disclosure relates in general to a light-emitting device, and more particularly to a light-emitting device with high process yield and high device reliability.

### BACKGROUND

Since light emitting diode (LED) advantageously possesses the features of small volume, high brightness, short response time and long operating life, the light-emitting device formed of LEDs has been widely used in various fields such as illumination and sign board or used as the backlight source of display.

The current manufacturing process of light-emitting device mainly includes following steps. Firstly, the LEDs are packaged. Then, the packaged LEDs are soldered on the printed circuit board (PCB) using the surface mount technology (SMT) to form an electrical path and obtain a light-emitting device.

According to the most commonly used method of the surface mount technology, the LEDs are electrically connected to the PCB using solder. However, the method has its problem. That is, during the bonding or lamination process, the solder may easily overflow, and elements may contact each other through the melted solder and become short-circuited, and further make the light-emitting device fail.

Therefore, it has become a prominent issue for related technical staffs in the field to develop a light-emitting device capable of overcoming the above disadvantages and at the same time increasing the process yield and the device reliability.

### SUMMARY

The invention is directed towards a light-emitting device.

The light-emitting device of the invention includes a light-emitting unit, an electrode unit, and an insulating unit.

The light-emitting unit includes an illuminator and a packaging sealant. The illuminator generates an optical energy by way of electroluminescence, and the packaging sealant is formed on a part of a surface of the illuminator.

The electrode unit includes a first electrode and a second electrode respectively formed on the surface of the illuminator on which no packaging sealant is formed.

The insulating unit is formed on the surface of the light-emitting unit and includes a first insulating layer protruded between the first electrode and the second electrode.

When the light-emitting device of the invention is electrically connected to an external circuit board using solder, the insulating unit effectively separates the elements to avoid the elements being short-circuited by the solder overflowing. The invention not only increases process yield and device reliability but also reducing production cost.

The above and other aspects of the invention will become better understood with regard to the following detailed description of the preferred but non-limiting embodiment (s). The following description is made with reference to the accompanying drawings.

### BRIEF DESCRIPTION OF THE DRAWINGS

FIG. 1 is a cross-sectional view illustrating a light-emitting device according to a first embodiment of the invention;

FIG. 2 is a top view illustrating a light-emitting device according to a first embodiment of the invention using FIG. 1 as an example;

FIG. 3 is a cross-sectional view illustrating an implementation of a light-emitting device according to a first embodiment of the invention;

FIG. 4 is a cross-sectional view illustrating another implementation of a light-emitting device according to a first embodiment of the invention;

FIG. 5 is a top view illustrating another implementation of a light-emitting device according to a first embodiment of the invention using FIG. 4 as an example;

FIG. 6 is a cross-sectional view illustrating an alternate implementation of a light-emitting device according to a first embodiment of the invention;

FIG. 7 is a cross-sectional view illustrating a light-emitting device according to a second embodiment of the invention;

FIG. 8 is a cross-sectional view illustrating another implementation of a light-emitting device according to a second embodiment of the invention;

FIG. 9 is a cross-sectional view illustrating an alternate implementation of a light-emitting device according to a second embodiment of the invention;

FIG. 10 is a top view illustrating a light-emitting device according to a third embodiment of the invention;

FIG. 11 is a 3D diagram illustrating a light-emitting device according to a fourth embodiment of the invention;

FIG. 12 is a 3D diagram illustrating another implementation of a light-emitting device according to the fourth embodiment of the invention;

FIG. 13 is a 3D diagram illustrating a light-emitting device according to a fifth embodiment of the invention;

FIG. 14 is a 3D diagram similar to FIG. 11 illustrating a structural implementation of a light-emitting device according to the fourth embodiment of the invention not including a transparent substrate;

FIG. 15 is a 3D diagram similar to FIG. 13 illustrating a structural implementation of a light-emitting device according to the fifth embodiment of the invention not including a transparent substrate;

FIG. 16 is a cross-sectional view illustrating a light-emitting device according to a first embodiment of the invention being electrically connected to an external circuit board;

FIG. 17 is a cross-sectional view illustrating a light-emitting device according to a second embodiment of the invention being electrically connected to an external circuit board.

### DETAILED DESCRIPTION

It should be noted that in the embodiments of the invention disclosed below, similar or identical elements are designated by the same reference numeral. Relevant technical contents, features and effects of the invention are disclosed in following descriptions.

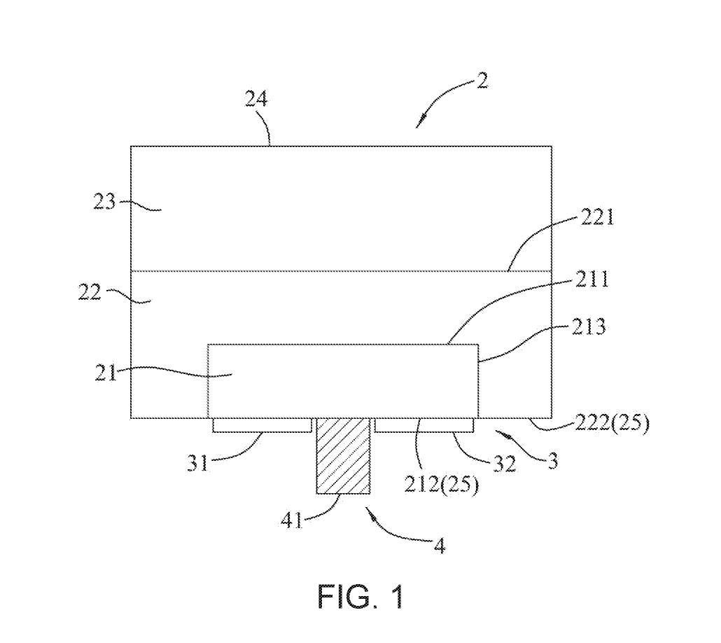

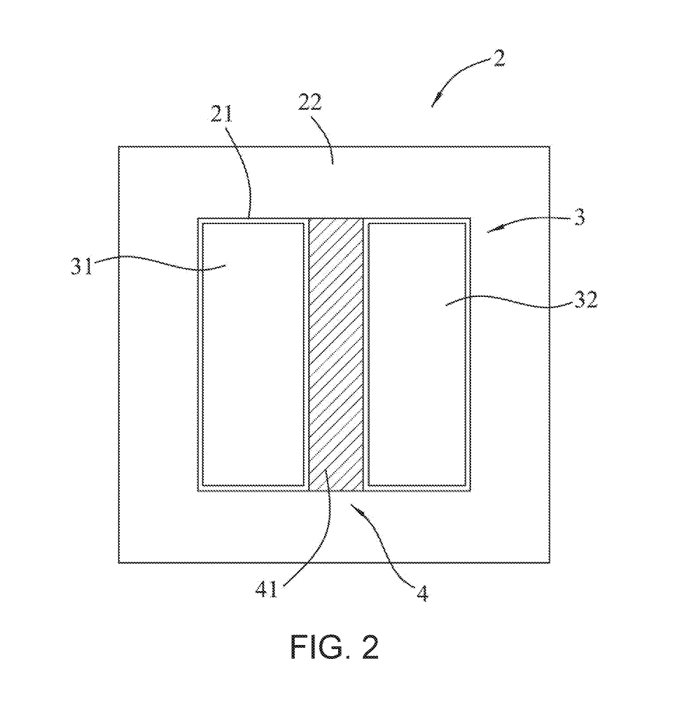

Refer to FIG. 1 and FIG. 2. The light-emitting device according to the first embodiment of the invention includes a light-emitting unit 2, an electrode unit 3, and an insulating unit 4.

The light-emitting unit 2 includes an illuminator 21, a packaging sealant 22, and a transparent substrate 23. The illuminator 21 generates an optical energy by way of electroluminescence, and has a first surface 211, a second surface 212 opposite to the first surface 211, and a circumferential surface 213 connecting the first surface 211 and the second surface 212. The packaging sealant 22 is formed on the circumferential surface 213 and the first surface 211, and has a third surface 221 and a fourth surface 222 opposite to the third surface 221. The illuminator 21 is disposed towards the third surface 221 from the fourth surface 222 and covered by the packaging sealant 22. The transparent substrate 23 is correspondingly formed above the first surface 211 and connected to the third surface 221 of the packaging sealant 22.

The electrode unit 3 includes a first electrode 31 and a second electrode 32 respectively formed on the second surface 212 of the illuminator 21.

It should be noted that the light-emitting unit 2 has a light output surface 24, and a bottom surface 25 opposite to the light output surface 24. The bottom surface 25 is composed of the second surface 212 of the illuminator 21 and the fourth surface 222 of the packaging sealant 22. The illuminator 21 has an N-type semiconductor (not illustrated) and a P-type semiconductor (not illustrated), and the first electrode 31 and the second electrode 32 electrically are connected to the N-type semiconductor and the P-type semiconductor, respectively. To put it in greater details, the illuminator 21 has an N-type semiconductor layer, a light-emitting layer formed on the N-type semiconductor layer, and a P-type semiconductor layer formed on the light-emitting layer. The first electrode 31 and the second electrode 32 are formed on the surface of the N-type semiconductor layer and the surface of the P-type semiconductor layer respectively.

In the first embodiment, detailed descriptions for the structure and material selection of the light-emitting unit 2 and the electrode unit 3 are omitted because these descriptions are generally known to any person ordinarily skilled in the technology field of the invention and are not the main technical features of the invention.

The insulating unit 4 is formed on the bottom surface 25, and includes a first insulating layer 41 protruded between the first electrode 31 and the second electrode 32. The first insulating layer 41 is formed of an insulating material, and can be formed between the first electrode 31 and the second electrode 32 by way of screen printing, UV curing, exposure and development, or 3D printing. In the first embodiment of the invention, the insulating unit 4 is disposed for the purpose of isolating the solder coated on the first electrode 31 from the solder coated on the second electrode 32 during the soldering process. Therefore, the insulating material used in the insulating unit 4 can resist high temperature during the manufacturing process. Exemplarily but not restrictively, the first insulating layer 41 is formed of a material selected from epoxy resin, photoresist, plastic, silicon dioxide (SiO₂), silicone, or a combination thereof. These materials all possess excellent chemical resistance, heat resistance and mechanical properties.

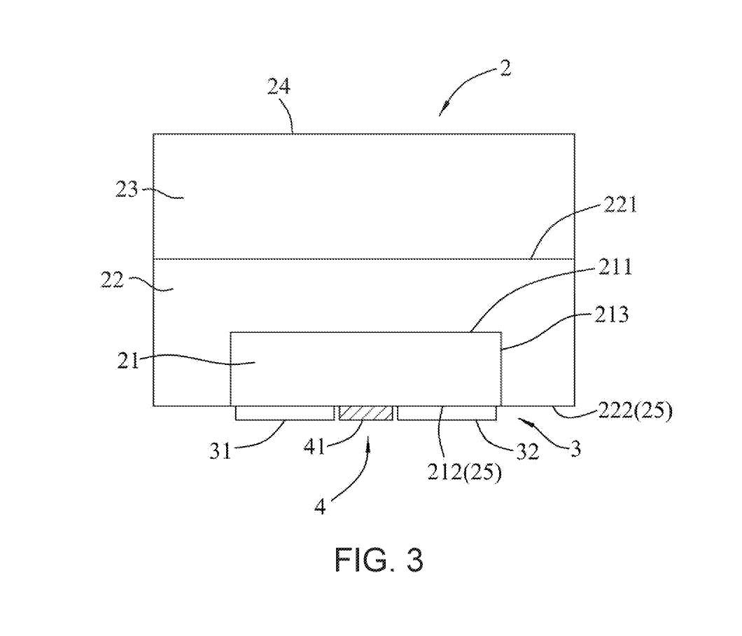

It should be noted that the first insulating layer 41 can be protruded between the first electrode 31 and the second electrode 32 as indicated in FIG. 1. Since the first insulating layer 41 is formed of an anti-tinning material, the first insulating layer 41 can be aligned with the first electrode 31 and the second electrode 32 as indicated in FIG. 3, not only achieving the same effect but also saving cost.

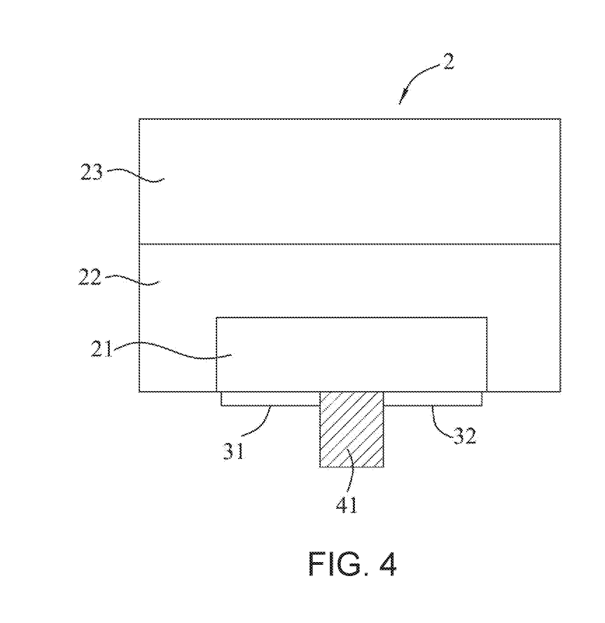

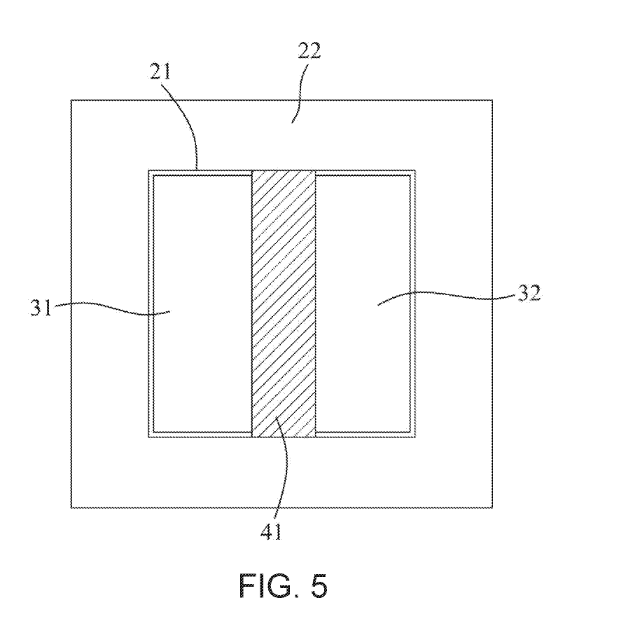

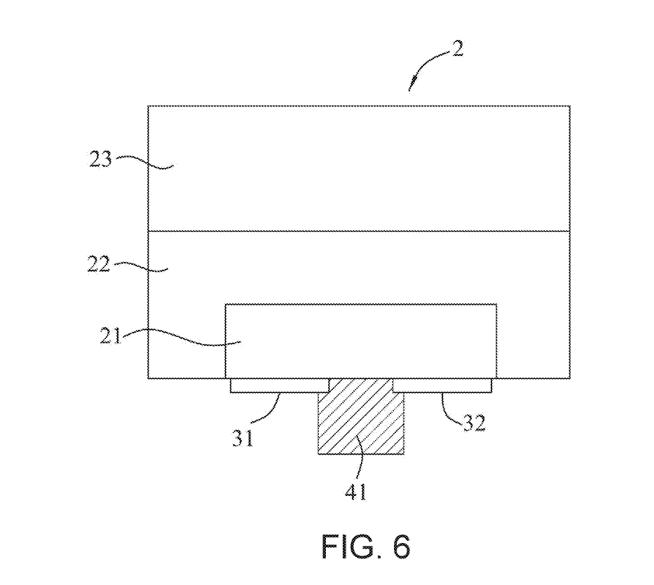

It should be noted that apart from being formed between the first electrode 31 and the second electrode 32 without contacting the first electrode 31 or the second electrode 32 as indicated in FIG. 1 and FIG. 2, the first insulating layer 41 can contact the first electrode 31 and the second electrode 32 as indicated in FIG. 4 and FIG. 5. Or, the first insulating layer 41 can cover a part of the first electrode 31 and the second electrode 32 as indicated in FIG. 6 and can be adjusted according to manufacturing conditions or cost consideration without specific restrictions.

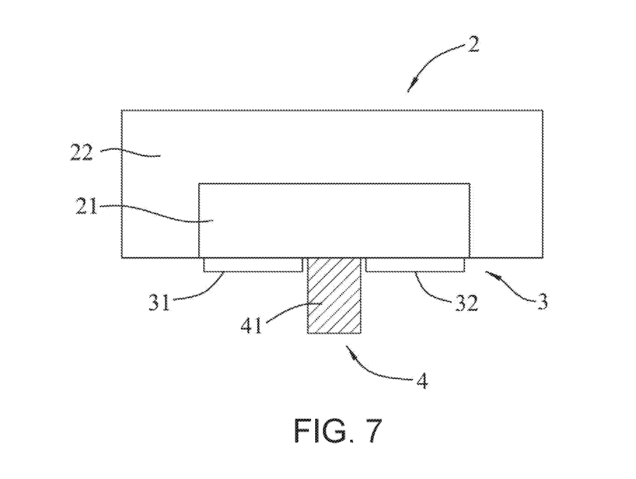

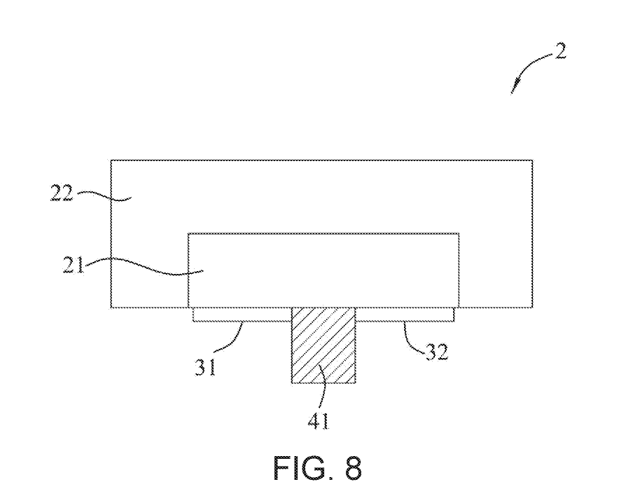

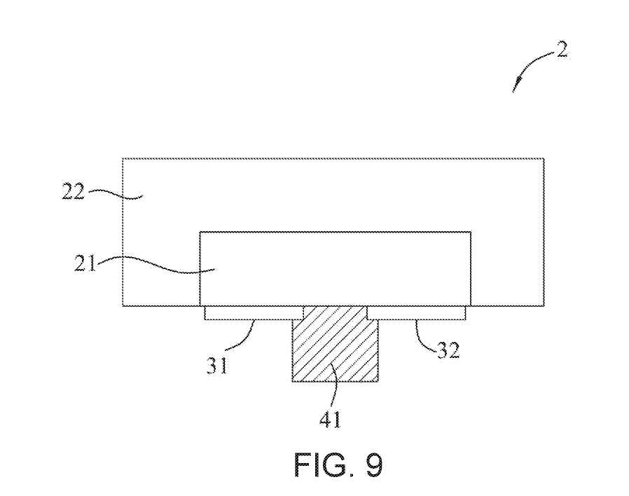

Refer to FIG. 7 to FIG. 9. The light-emitting device according to the second embodiment of the invention is basically the same as the first embodiment except that the light-emitting device of the second embodiment does not include the transparent substrate 23 and therefore can achieve the trend of thinning design and satisfy the market demand better.

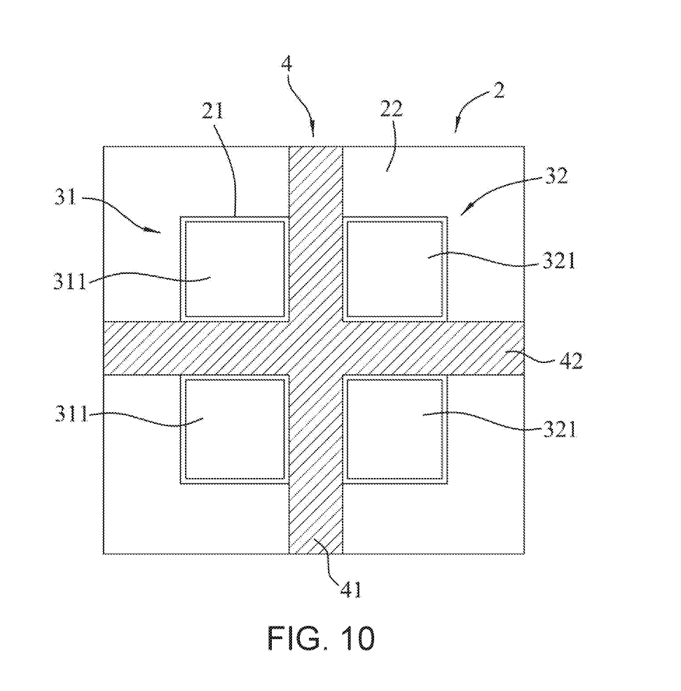

Refer to FIG. 10. The light-emitting device according to the third embodiment the invention is basically the same as the first embodiment except that the insulating unit 4 further includes at least one second insulating layer 42. The second insulating layer 42 is formed on the surfaces of the first electrode 31 and the second electrode 32, and divides the first electrode 31 and the second electrode 32 into at least two first electrode regions 311 and at least two second electrode regions 321, respectively. In FIG. 10, the insulating unit 4 further includes a second insulating layer 42, but the invention is not limited thereto. Furthermore, since the material selection and formation method of the second insulating layer 42 are the same as that of the first insulating layer 41, the similarities are not repeated here.

It should be noted that the edges of the first insulating layer 41 and the second insulating layer 42 can be aligned with that of the illuminator 21 (as indicated in FIG. 2), or can extend to the peripheral of the packaging sealant 22, and can be adjusted according to manufacturing conditions or cost consideration, and is not subject to specific restrictions. In FIG. 10, it is exemplified that the first insulating layer 41 and the second insulating layer 42 respectively extend to the peripheral of the packaging sealant 22, but the invention is not limited thereto.

It should be noted that in the third embodiment of the invention, the second insulating layer 42 further divides the first electrode 31 and the second electrode 32, which are separated by the first insulating layer 41, into two first electrode regions 311 and two second electrode regions 321, respectively.

When the light-emitting device is electrically connected to an external circuit board in subsequent process, the first electrode regions 311 and the second electrode regions 321 can achieve alignment function and make the light-emitting device connected to the external circuit board more accurately.

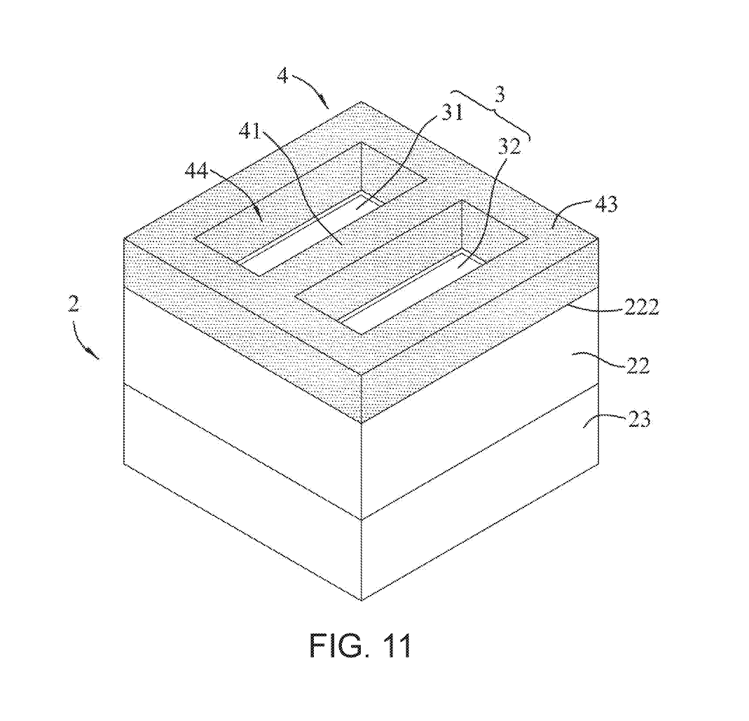

Refer to FIG. 11. The light-emitting device according to the fourth embodiment of the invention is basically the same as the first embodiment except that the insulating unit 4 further includes a third insulating layer 43. The third insulating layer 43 is formed on the fourth surface 222 of the packaging sealant 22 and interconnected with the first insulating layer 41. Specifically, the first insulating layer 41 and the third insulating layer 43 are protruded between the light-emitting unit 2 and the electrode unit 3, and define two recesses 44 together with the light-emitting unit 2 and the electrode unit 3.

In the fourth embodiment of the invention, when the light-emitting device is electrically connected to an external circuit board by using solder, the recesses 44 not only provide alignment function but further limit the solder such that the solder will not overflow and make the elements become short-circuited or current leakage.

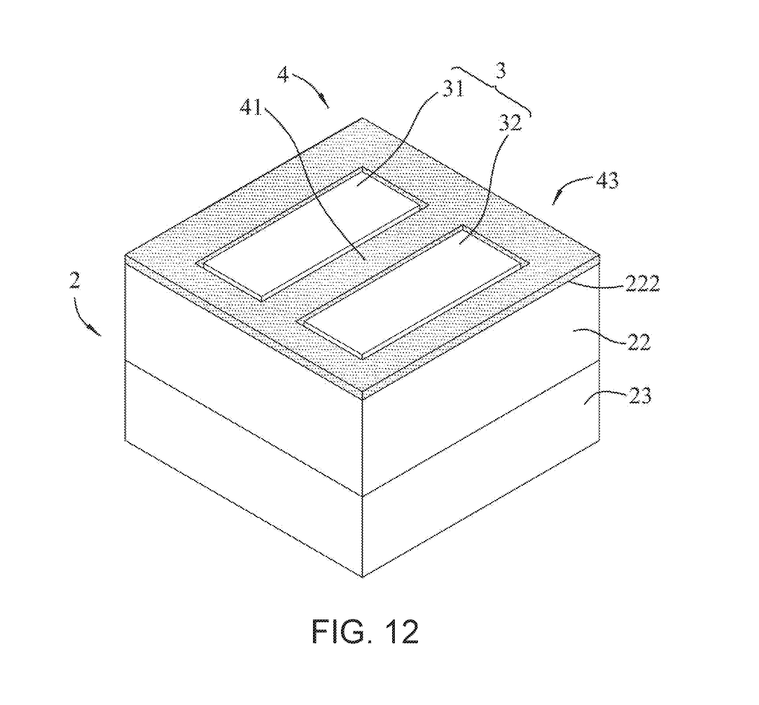

It should be noted that the first insulating layer 41 and the third insulating layer 43 can be protruded between the light-emitting unit 2 and the electrode unit 3, or as indicated in FIG. 12, can be aligned with the electrode unit 3 as disclosed in the first embodiment.

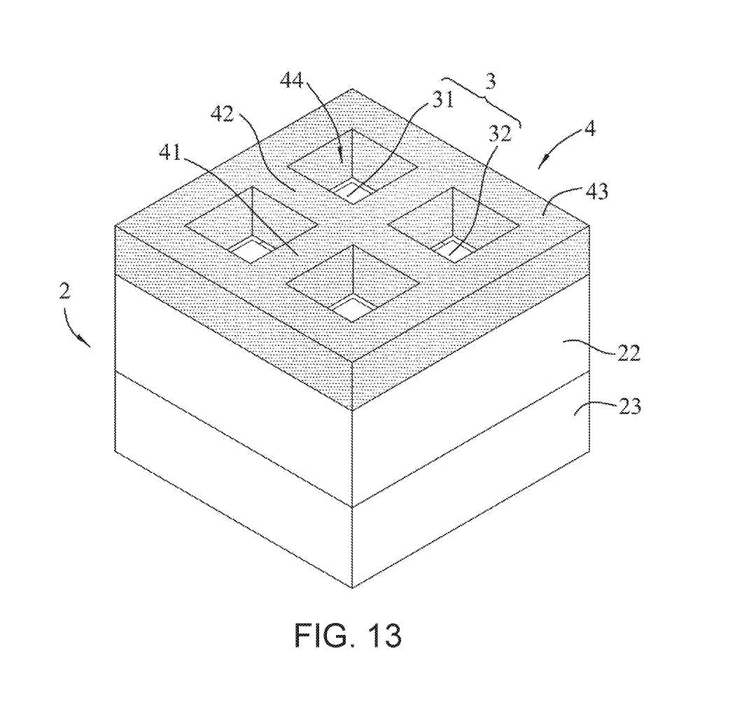

Refer to FIG. 13. The light-emitting device according to the fifth embodiment of the invention is basically the same as the fourth embodiment except that the insulating unit 4 further includes a second insulating layer 42. That is, the third insulating layer 43 is interconnected with the first insulating layer 41 and the second insulating layer 42. As disclosed in the fourth embodiment, the first insulating layer 41, the second insulating layer 42 and the third insulating layer 43 define four recesses 44 together with the light-emitting unit 2 and the electrode unit 3.

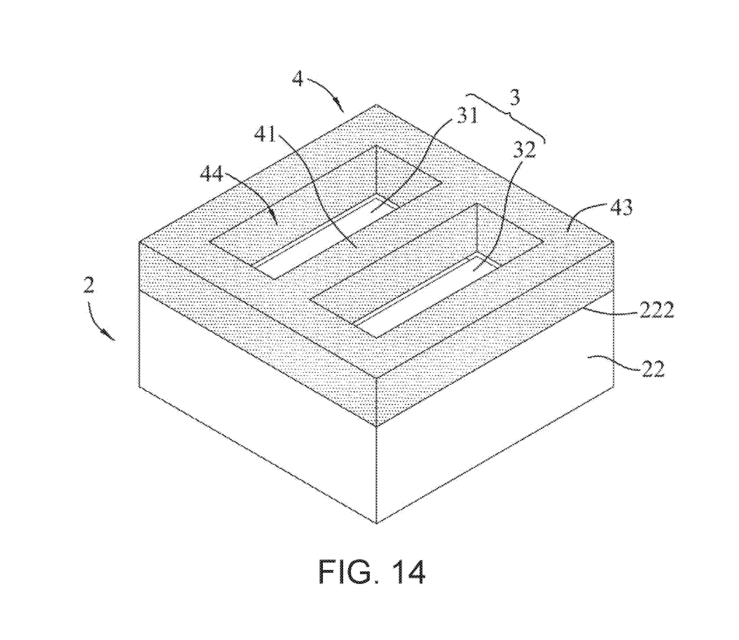

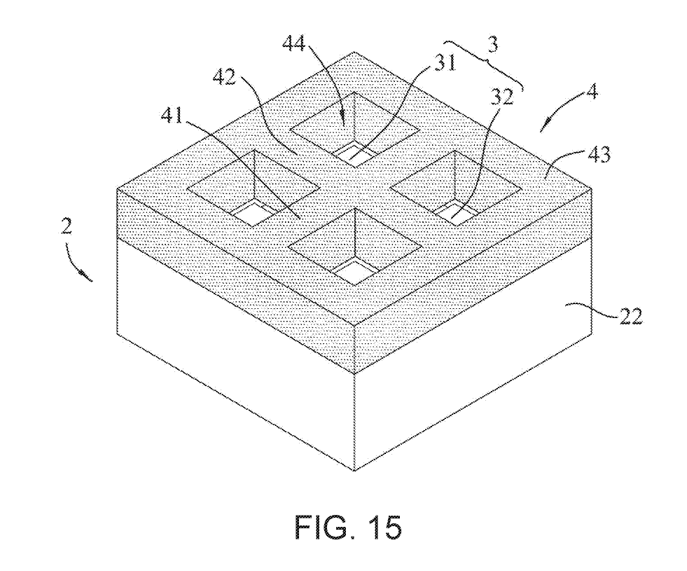

Refer to FIG. 14 and FIG. 15. Like the second embodiment, the light-emitting device according to the fourth embodiment and the fifth embodiment of the invention does not include the transparent substrate 23, such that the trend of thinning design can be achieved.

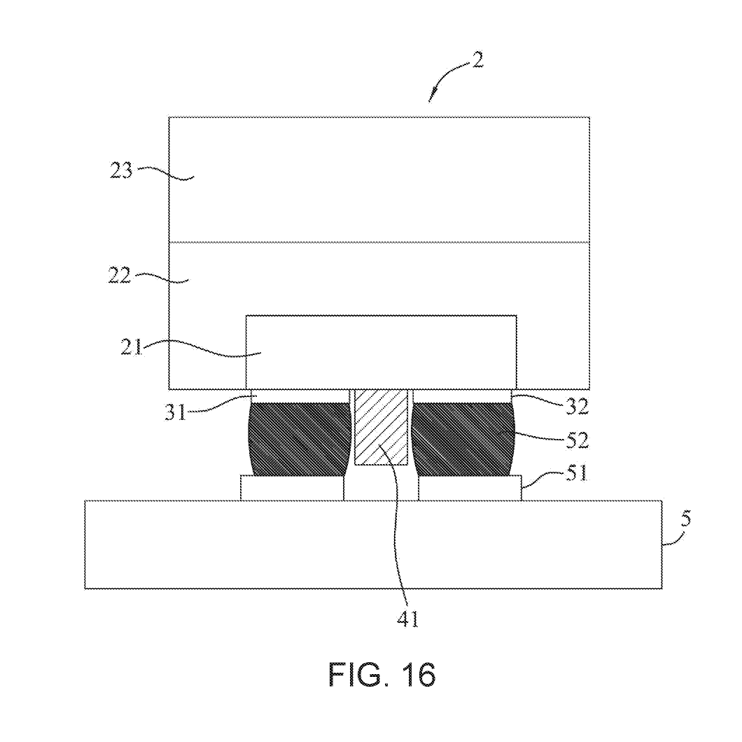

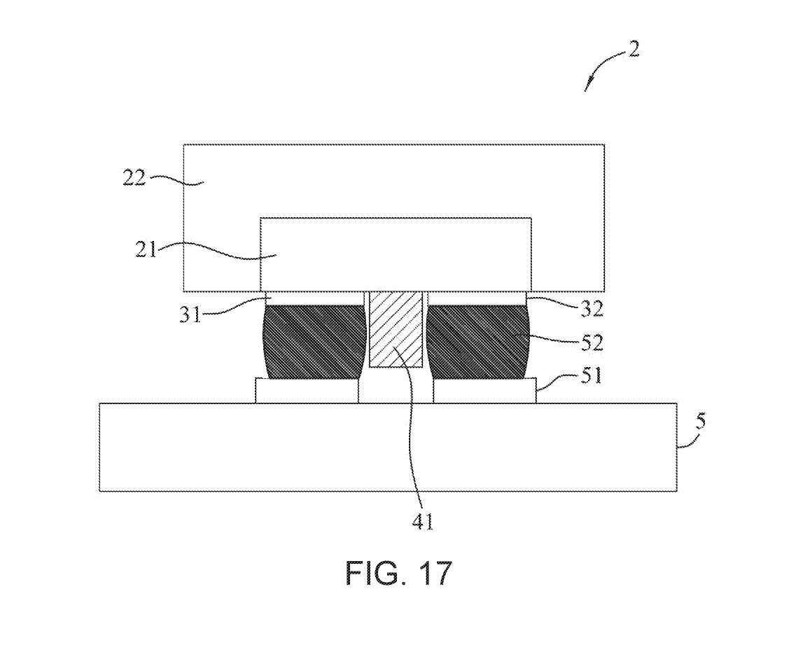

Refer to FIG. 16 and FIG. 17. FIG. 16 and FIG. 17 are cross-sectional views illustrating a light-emitting device being electrically connected to an external circuit board 5 using the first and the second embodiments as an example. In the first embodiment and the second embodiment of the invention, the process of connecting the light-emitting device to an external circuit board 5 includes following steps. Firstly, a plurality of pads 51 are disposed on the external circuit board 5. Next, a solder 52 is printed on the pads 51. Then, the light-emitting devices of the first and second embodiments are electrically connected to the external circuit board 5.

According to the light-emitting device illustrated in the first embodiment to the fifth embodiment of the invention, the first electrode 31 and the second electrode 32 are isolated by the insulating unit 4 to avoid the elements being short-circuited by the solder overflowing, not only effectively increasing process yield and device reliability, but further reducing production cost. On the other hand, in the light-emitting device of the invention, through the disposition of the first insulating layer 41 and the second insulating layer 42, the quantities of the first electrode regions 311 and the second electrode regions 321 can be flexibly adjusted to meet the requirements of product types or alignment assembly in subsequent process.

To summarize, when the light-emitting device of the invention is electrically connected to the external circuit board 5, the insulating unit 4 not only avoids the elements contacting each other and being short-circuited by the solder overflowing, but also advantageously increases process yield and device reliability and reduces production cost. Therefore, the light-emitting device of the invention really can achieve the objects of the invention.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A light-emitting device comprising:
a light-emitting unit comprising an illuminator and a packaging sealant, wherein the illuminator generates an optical energy by way of electroluminescence, and the packaging sealant is formed on a part of a surface of the illuminator;
an electrode unit comprising a first electrode and a second electrode respectively formed on the surface of the illuminator on which no packaging sealant is formed; and
an insulating unit formed on a surface of the light-emitting unit, wherein the insulating unit includes a first insulating layer protruded between the first electrode and the second electrode.

2. The light-emitting device according to claim 1, wherein, the illuminator has a first surface, a second surface opposite to the first surface, and a circumferential surface connecting the first surface and the second surface, the packaging sealant is formed on the circumferential surface and the first surface, and the electrode unit is formed on the second surface of the illuminator.

3. The light-emitting device according to claim 2, wherein the packaging sealant has a third surface and a fourth surface opposite to the third surface, and the illuminator is disposed towards the third surface from the fourth surface and covered by the packaging sealant.

4. The light-emitting device according to claim 3, wherein the insulating unit further comprises at least one second insulating layer dividing the first electrode and the second electrode into at least two first electrode regions and at least two second electrode regions respectively.

5. The light-emitting device according to claim 3, wherein the insulating unit further comprises a second insulating layer dividing the first electrode and the second electrode into two first electrode regions and two second electrode regions respectively.

6. The light-emitting device according to claim 5, wherein the insulating unit further comprises a third insulating layer formed on the fourth surface of the packaging sealant and interconnected with the first insulating layer and the second insulating layer.

7. The light-emitting device according to claim 3, wherein the insulating unit further comprises a third insulating layer formed on the fourth surface of the packaging sealant and interconnected with the first insulating layer.

8. The light-emitting device according to claim 3, wherein the light-emitting unit further comprises a transparent substrate correspondingly formed above the first surface of the illuminator and connected to the third surface of the packaging sealant.

9. The light-emitting device according to claim 3, wherein, the illuminator has an N-type semiconductor and a P-type semiconductor, and the first electrode and the second electrode are electrically connected to the N-type semiconductor and the P-type semiconductor respectively.

10. The light-emitting device according to claim 1, wherein the insulating unit comprises a material, and the material is selected from epoxy resin, photoresist, plastic, silicon dioxide, silicon resin, and combinations thereof.
